(19) United States
(12) Patent Application Publication
(10) Pub. No.: US 2012/0132260 A1
(43) Pub. Date: May 31, 2012

(54) Assembly, Sub-Structure and Photovoltaic System

(76) Inventors: Thomas Hirsch, Landshut (DE); Claus Alt, Landshut (DE); Harald Heinrich, Pfeffenhausen (DE)

(21) Appl. No.: 12/955,273

(22) Filed: Nov. 29, 2010

(51) Int. Cl. H01L 31/048

(52) U.S. Cl. 136/251

(57) ABSTRACT

An assembly includes a first and a second apparatus, each to accommodate at least one photovoltaic module. The first apparatus is coupled by its first end to a first end of the second apparatus so that a second end of the first apparatus located opposite the first end, and a second end of the second apparatus located opposite the first end are arranged at a distance to each other on a surface which is at a distance from the coupling of the first ends.

### TECHNICAL FIELD

The invention concerns an assembly to accommodate photovoltaic modules, a sub-structure with at least two such assemblies, as well as a photovoltaic system.

### BACKGROUND

The energy in solar radiation can be converted into electric energy by means of photovoltaic modules. Photovoltaic modules are normally mounted onto a sub-structure, which in turn is attached to a substrate, such as a roof, for example. Photovoltaic modules are conventionally mounted onto mounting tripods on flat roofs or on installations known as outdoor arrays. In this case one single photovoltaic module is mounted to each mounting tripod. These mounting tripods must additionally be supplied with weights or have to be screwed to the substrate in order to ensure the needed stability, for example, against buoyancy forces when wind acts on the installation. Accordingly, the flat roof must be sufficiently stable to withstand the additional, not inconsiderable weight, and/or lead holes must be drilled through the roof skin and then reliably waterproofed again.

### SUMMARY

It is desirable to specify an assembly to accommodate photovoltaic modules, a sub-structure with at least two such assemblies, and also a photovoltaic system in order to mount the photovoltaic modules in a variable manner.

In one embodiment of the invention, an assembly comprises a first and a second apparatus each to accommodate at least one photovoltaic module. The first apparatus is coupled by one first end to a first end of the second apparatus such that, a second end of the first apparatus located opposite the first end, and a second end of the second apparatus located opposite the first end, are arranged at a distance to each other on a surface. The surface is located at a distance from the coupling of the first ends.

In one exemplary embodiment, one accommodation area of the first and of the second apparatus for the at least one photovoltaic module each extends from the first end and to the second end of the first and of the second apparatus.

By means of this kind of coupling of the first and of the second apparatus, the assembly can accommodate two photovoltaic modules that are arranged obliquely to the surface.

In one exemplary embodiment, the assembly comprises at least one base element, each of which is connected to the second end of the first apparatus and to the second end of the second apparatus, so that the at least one base element is arranged on the surface. The base element can comprise at least one elongated rod that extends from the second end of the first apparatus to the second end of the second apparatus.

The base element stabilizes the assembly and prevents the second ends from moving relative to one another on the surface.

In one embodiment, the first and the second apparatus each form an oblique flank between the first and the second end with respect to the at least one base element, so that the first ends of the first and of the second apparatus are arranged between the second end of the first apparatus and the second end of the second apparatus.

Due to the arrangement of the first ends between the second ends, the advantage is that when photovoltaic modules are coupled to the assembly, the primary surfaces of incident radiation of the photovoltaic modules are directed away from one another. In addition, the first and the second apparatus can each enclose an angle of less than 90 degrees, in particular, less than 20 degrees between the second side and the at least one base element. In particular, the apparatus can enclose an angle of about 18 degrees with the base element, which is the angle of minimum solar angle in winter in Germany. Different angles can be enclosed at different locations, which can be determined as a function of the smallest solar attitude. The angle of the first apparatus and the angle of the second apparatus can be of equal size; they can also be different.

In one exemplary embodiment, the first and the second apparatus each comprises at least two elongated rods which are arranged in the same direction at a distance to each other and each extending from the first end to the second end, and which are each designed to accommodate the at least one photovoltaic module.

In one exemplary embodiment, the assembly comprises a coupling apparatus for coupling of the first end of the first apparatus to the first end of the second apparatus, wherein the coupling apparatus has a first element and a second element. The elongated rods of the first apparatus and the elongated rods of the second apparatus each engage in opposing sides of the first element in order to couple the first apparatus to the second apparatus. The second element is designed so as to be coupled to the first element such that the particular, at least one photovoltaic module is fixed in position at the particular first end by means of the coupling apparatus.

Due to this coupling apparatus, the assembly is stabilized so that the elongated rods of the first and of the second apparatus are braced against each other so that they are essentially self-supporting, similar to an arch. In addition, the two photovoltaic modules can be easily coupled to the apparatus with the same coupling element. Also, in this manner fewer assembly steps are needed.

In one embodiment the assembly comprises a first and a second base element, which are each arranged transversely to the longitudinal direction of the elongated rods at a distance to each other on the surface, wherein the two elongated rods of the first apparatus are coupled to the first base element at the second end of the first apparatus, and the two elongated rods of the second apparatus are coupled to the second base element at the second end of the second apparatus. With these base elements the assembly can be mounted onto the surface, for example, of a flat roof, an inclined roof, or an outdoor area.

The elongated rods can each be insertable into the base element to make the connection. The base elements can each be designed to accommodate one attachment element for the mounting of the particular at least one photovoltaic module. For example, the photovoltaic modules can be coupled by their second ends to the apparatus.

The at least one elongated rod of the base element can be coupled to the first base element and to the second base element in order to couple the first base element to the second base element. This will essentially prevent the base elements from being able to move relative to each other.

In another exemplary embodiment, the assembly comprises at least two triangular-shaped side elements each being coupled to the other at the corners of the triangular shape, so that three surfaces are enclosed. Two surfaces are designed so as to be coupled to the at least one photovoltaic module. The third surface is designed in order to be arranged on the surface.

A sub-structure for a photovoltaic system comprises at least one first and one second such assembly. The at least one first and one second assembly are coupled together.

The at least one first and one second apparatus can be coupled together so that the first apparatus is arranged transverse to the longitudinal direction of the photovoltaic modules next to the second apparatus. The at least one first and one second apparatus can be coupled together so that the first apparatus is arranged transverse to the longitudinal direction of the photovoltaic modules next to the second apparatus.

A photovoltaic system comprises at least one such assembly and at least the first and the second photovoltaic modules that are each coupled to the assembly so that the primary surface of incident radiation of the first photovoltaic module is directed differently to the primary surface of incident radiation of the second photovoltaic module.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 is a schematic view of an assembly according to one embodiment;

FIG. 2 is a schematic view of a sub-structure according to one embodiment;

FIG. 3 is a schematic view of a photovoltaic system according to one embodiment;

FIG. 4 is a detailed schematic view of a coupling apparatus according to one embodiment;

FIG. 5 is a detailed schematic view of the assembly according to one embodiment;

FIG. 6 is a schematic view of a base element according to one embodiment;

FIG. 7 is a schematic, cross section of an elongated rod according to one embodiment;

FIG. 8 is a schematic view of an assembly according to one embodiment;

FIG. 9 is a schematic view of a sub-structure according to one embodiment; and

FIG. 10 is a detailed, schematic view of a section of an assembly from FIG. 8, according to one exemplary embodiment.

The same or equivalent elements, or elements having the same functional effect, are identified in the figures by the same reference numbers.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

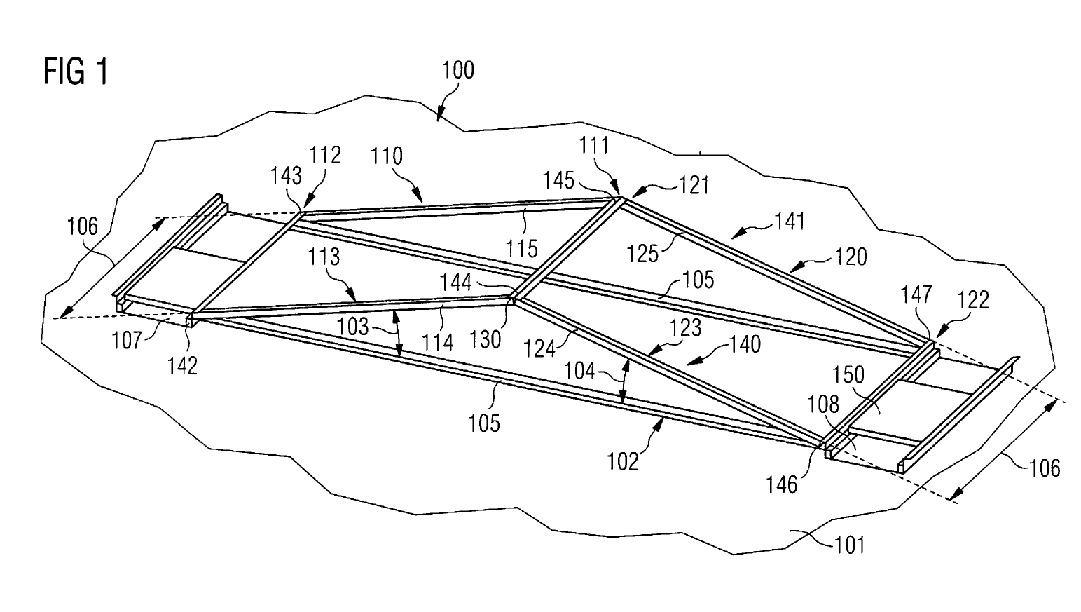

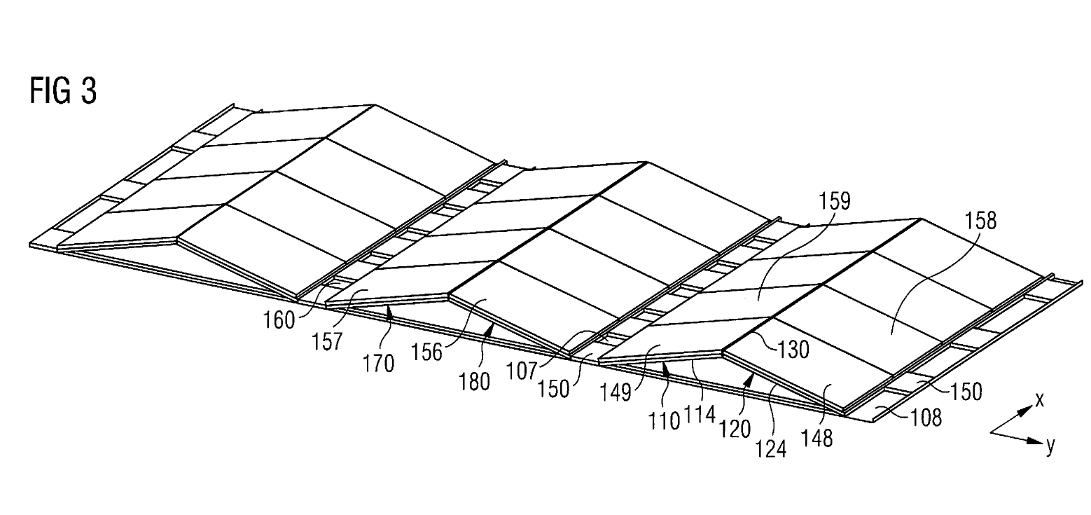

FIG. 1 shows an assembly 100 to accommodate two photovoltaic modules 148, 149 (FIG. 3). The assembly 100 is arranged on a surface 101. The assembly 100 comprises two triangular-shaped side elements 140 and 141. The triangular-shaped side elements 140 and 141 are arranged on the surface at a distance to each other so that one side runs essentially along the surface 101, in particular, essentially parallel to surface 101. The two side elements 140 and 141 are coupled together. The first side element 140 has three corners 142, 144 and 146. The second side element 141 has three corners 143, 145 and 147. The two side elements 140 and 141 are connected together at the corresponding corners 142 and 143, 144 and 145 and also 146 and 147, so that two accommodation areas 113 and 123 are created each to accommodate one of the photovoltaic modules 148 and/or 149, respectively.

The accommodation areas 113 and 123 are each aligned obliquely to the surface 101. If the photovoltaic modules 148, 149 are mounted to the assembly 100 (FIG. 3), then the photovoltaic modules 148, 149 accordingly have an inclination with respect to the surface 101. The accommodation area 113 together with the surface encloses roughly the angle 103. The accommodation area 123 together with the surface encloses roughly the angle 104. The angles 103 and 104, and in particular the size of the angles, are essentially equal. In another exemplary embodiment, the angles 103 and 104 can be different from each other, for example, angles 103 104 can differ from each other by 33% or less, in particular by 20% or less. Angles 103 and 104 can differ from each other by more than 33%, for example, by 40% or more. In particular, the angles 103 and 104 are each acute angles, that is, less than 90 degrees. In the illustrated exemplary embodiment, the angle 103 is a positive angle and angle 104 is a negative angle (with respect to the X-axis), so that the accommodation areas 113 and 123 are aligned obliquely opposite each other with respect to surface 101. The apex of angle 103 is located at the corners 142 and 143. The apex of angle 104 is located at the corners 146 and 147.

The assembly 100 comprises a first apparatus 110 that features the accommodation area 113. The assembly comprises a second apparatus 120 that features the accommodation area 123. Apparatus 110 and 120 are arranged obliquely to the surface 101. The apparatus 110 has a first end 111 that is arranged at the corners 144 and 145. The second apparatus 120 has a first end 121 that is arranged at the corners 144 and 145. The apparatus 110 has a second end 112 that is arranged opposite to the first end 111 at the corners 142 and 143. The second apparatus 120 has a second end 122 that is arranged opposite to the first end 121 at the corners 146 and 147. The apparatus 110 extends between the first and second ends 111 and 112 and thus forms the accommodation area 113. The second apparatus 120 extends between the first and second ends 121 and 122 and thus forms the accommodation area 123.

The first and the second apparatus 110 and 120 are coupled together at their first ends 111 and 121 by means of a coupling apparatus 130. Apparatus 110 is coupled at its second end 112 to a base element 107. The second apparatus 120 is coupled at its second end 122 to a base element 108. Apparatus 110 is additionally coupled at its second end 112 to a base element 102. The second apparatus 120 is coupled at its second end 122 to a base element 102. The base element 107 and the base element 108 are each coupled to base element 102.

The apparatus 110 comprises two elongated rods 114 and 115 whose longitudinal direction runs between the first end 111 and the second end 112. The elongated rods 114 and 115 are arranged transversely at a distance 106 to the longitudinal direction. The distance 106 roughly corresponds to the width of the photovoltaic module 149, which is to be coupled to the apparatus 110. The apparatus 110 and 120 are designed to accommodate the photovoltaic modules 148 and 149 either upright or transversely. The longer sides of the photovoltaic modules can thus be arranged along the elongated rods 114 and 115 or the shorter sides of the photovoltaic modules can be arranged along the elongated rods 114 and 115.

The second apparatus 120, whose structural design is essentially equivalent to that of the first apparatus 110, comprises two elongated rods 124 and 125 whose longitudinal direction runs between the first end 121 and the second end 122.

For example, for an upright assembly of the photovoltaic modules, if the latter have a width of about 110 cm, then the distance 106 to the particular middle of the elongated rods 114 and 115 and/or 124 and 125, is about 110 cm plus/minus 2%. For smaller modules, this distance can also be smaller than 110 cm, for example, 80 cm plus/minus 2%. For larger modules, this distance can also be greater than 110 cm, for example, 150 cm plus/minus 2%. The distance 106 to the particular middle of the elongated rods 114 roughly corresponds to the width of the photovoltaic modules used.

For example, for a transverse assembly of the photovoltaic modules, if the latter have a width of about 160 cm, then the distance 106 to the particular middle of the elongated rods 114 and 115 is about 160 cm plus/minus 2%. For smaller modules, this distance can also be smaller than 160 cm, for example, 130 cm plus/minus 2%. For larger modules, this distance can also be greater than 160 cm, for example, 200 cm plus/minus 2%. The distance 106 to the particular middle of the elongated rods 114 roughly corresponds to the width of the photovoltaic modules used.

The elongated rods 114, 115, 124 and 125 each have, for example, a cross-sectional shape of a T-profile, as will be explained in greater detail in connection with FIG. 7. The elongated rods 114, 115, 124 and 125 can also have a different shape that is designed to support at least one photovoltaic module. The elongated rods 114, 115, 124 and 125 can be aluminum, galvanized steel or another material, such as a plastic or synthetic material, which is sufficiently stable to support photovoltaic modules over a longer period of time, for example, 20 years, in a dependable manner.

The base element 102 comprises two elongated rods 105. The elongated rods 105 each have, for example, a cross-sectional shape of a T-profile. The elongated rods 105 can also have a different shape that is designed to prevent the base elements 107 and 108 from moving relative to each other when the elongated rods 105 are each coupled to the base elements 107 and 108. The elongated rods 105 can be aluminum, galvanized steel or another material, such as a plastic or synthetic material, which is sufficiently stable to support the base elements 107 and 108 over a longer period of time, for example, 20 years, in a dependable manner.

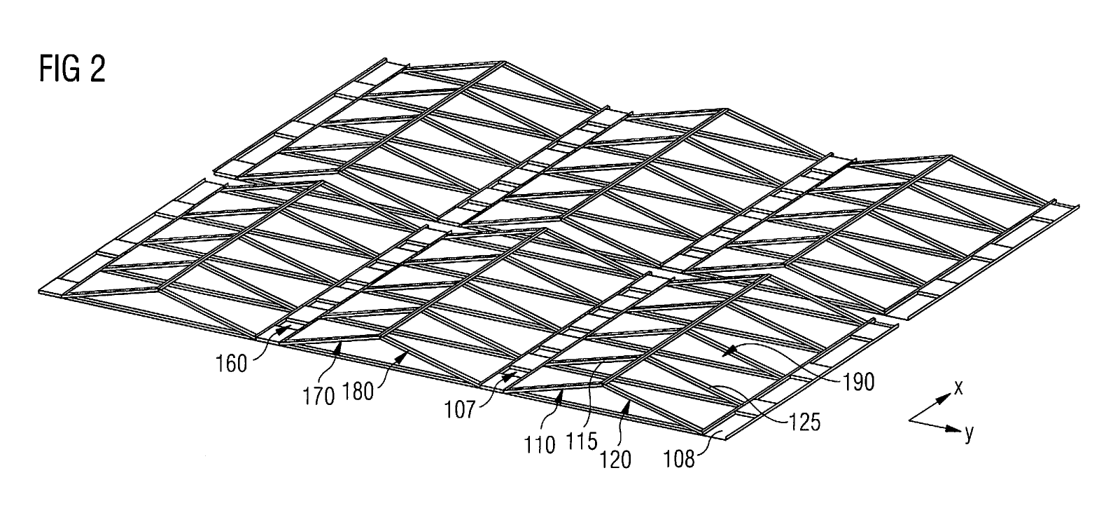

The base elements 107 and 108 are each designed so as to be coupled to opposing ends of the elongated rods 105. The base element 107 is designed so as to be coupled to the elongated rods 114 and 115. The base element 108 is designed so as to be coupled to the elongated rods 124 and 125. The base elements 107 and 108 are each designed so as to be coupled to elongated rods (not illustrated), as will be explained in greater detail in connection with FIG. 2. In addition, the base elements 107 and 108 are each designed to accommodate one a plurality of weighting elements 150. By means of the weighting element 150, the mount of the assembly 100 to the surface 101 can be improved.

Surface 101 comprises a flat roof, a flat-inclined roof, or even an outdoor area that is independent of any structures. The inclined roof is sloped, for example, at about 10 degrees or even at about 5 degrees. In particular, the flat roof comprises a foil-sealed roof, for example, a roof sealed with an ethylene-propylene-diene-rubber foil. The foil can also comprise other materials, for example different rubbers or bitumen.

Due to coupling of the elongated rods 114 and 124 and also 115 and 125 to the coupling element 130 at the first ends 111 and 121 and the coupling of the elongated rods 114 and 124 and also 115 and 125 to base elements 107 and 108, and also of base element 102 at the second ends 112 and 122, a structural support is created for two photovoltaic modules. The accommodation areas for the photovoltaic modules are each arranged obliquely to the substrate since the elongated rods of the first apparatus enclose the angle 103 with the base element, and the elongated rods of the second apparatus enclose the angle 104 with the base element. Therefore, the accommodation areas are aligned in different directions to each other. The elongated rods 114 and 124 and also 115 and 125 are thus coupled in a self-supporting manner, so that additional reinforcement in the direction of the surface 101 can be omitted.

FIG. 2 shows a sub-structure comprising a plurality of assemblies 100 that is designed to accommodate 6 times 8 photovoltaic modules. The sub-structure comprises the apparatus 110 and 120 and also additional apparatus 170, 180 and 190. The apparatus are each designed as explained in connection with the apparatus 110 and 120.

The apparatus 190 is arranged in the X-direction next to apparatus 120. Apparatus 190 and/or the elongated rods of the apparatus are coupled at one second end of the apparatus 190 to the base element 108, to which also the apparatus 120 is coupled. Apparatus 120 and the apparatus arranged next to the apparatus 120 in the X-direction, for example, apparatus 190, have a common base element 108. The base element 108 extends in the X-direction across several apparatus, for example, across four apparatus. The base element can also extend across more apparatus, for example, across six or more apparatus, or fewer apparatus, for example, three or fewer apparatus.

The apparatus 120 and 190 directly adjoining each other have a common elongated rod 125. Two apparatus each arranged directly side by side have a common elongated rod through which an accommodation area is formed for two photovoltaic modules. An accommodation area for a photovoltaic module is formed by the elongated rod 125; this area is provided on the apparatus 120, and an accommodation area for a photovoltaic module is formed by the elongated rod 125; this area is provided on the apparatus 190. Thus in the X-direction, by means of three elongated rods the two apparatus 120 and 190 are formed which are designed to accommodate two photovoltaic modules.

The apparatus 180 and 170 are arranged in the negative Y-direction, next to the apparatus 110. The apparatus 110 and the apparatus 180 are coupled to the common base element 107. On the side opposite the base element 107, apparatus 170 is coupled to an additional base element 160. The base elements 107, 108 and 160, which are structurally equivalent, are each designed to be coupled to one or more apparatus on two opposing sides of the base element. Due to this modular sub-structure, a large number of different sub-structures can be created with a limited number of different structural elements.

FIG. 3 shows a photovoltaic system with a portion of a sub-structure as explained in conjunction with FIG. 2 and with three times eight photovoltaic modules in three rows which are coupled to the sub-structure. The photovoltaic module 148 is coupled to the apparatus 120. The photovoltaic module 149 is coupled to the apparatus 120. A photovoltaic module 156 is coupled to the apparatus 180. A photovoltaic module 157 is coupled to the apparatus 170. A photovoltaic module 158 is coupled to the apparatus 120. The photovoltaic modules are each coupled at their first end to the particular apparatus by means of the coupling apparatus 130. One, two or more photovoltaic modules can be coupled by the single, common coupling apparatus 130, to one, two or more apparatus. The coupling apparatus extends across a corresponding number of photovoltaic modules. The photovoltaic modules each rest upon the elongated rods of the corresponding apparatus.

The modules are supported and mechanically stabilized by the elongated rods. Two photovoltaic modules directly adjoining each other in the X-direction rest upon a common, elongated rod. Only one photovoltaic module rests upon the elongated rod at the outer edge of a row in the X-direction and/or negative X-direction. For example, photovoltaic module 158 and photovoltaic module 148 rest together upon the elongated rod 124 in the middle between the two photovoltaic modules. The elongated rod 114 supports photovoltaic module 149 and a directly neighboring photovoltaic module 159.

The photovoltaic modules are each arranged on the primary surface of incident solar radiation, for example, for converting sunlight into electric energy. The primary surface of incident radiation is that surface upon which a preponderance of sunlight arrives during operation. The primary surface of incident radiation is facing away from surface 101. For this conversion the photovoltaic modules comprise semiconductor stacks, for example, of silicon or gallium arsenide. Other materials are also suitable for the corresponding conversion of energy, for example, organic solar cells. In particular, thin film photovoltaic modules are employed in which the semiconductor stack is deposited on a substrate. These thin film photovoltaic modules can be used without a frame, that is, without any additional, reinforcing frame. Such photovoltaic modules are also called thin film photovoltaic modules. Thin film photovoltaic modules have a greater efficiency in diffuse radiation in comparison to conventional, crystalline photovoltaic modules.

In a photovoltaic system according to FIG. 3, preferably thin film photovoltaic modules are used. For example, the Y-direction points roughly south. Accordingly, the photovoltaic modules 149, 159 and 157 are aligned to face north. Nonetheless, photovoltaic modules 149, 159 and 157 still efficiently convert radiant energy into electric energy since a relatively large amount of diffuse radiation is converted by the thin film photovoltaic modules. But an alignment of the photovoltaic system differing from the north-south direction can also be used efficiently, for example, in an east-west alignment or an intermediate alignment. Due to the population of the assemblies with photovoltaic modules on both sides, the efficiency of the photovoltaic system is increased in comparison to conventional photovoltaic modules in which only the one side is populated with photovoltaic modules. This is achieved through the use of thin film photovoltaic modules, which can also be operated profitably even when their primary surface of incident radiation is aligned to north. But also, crystalline photovoltaic modules can be employed on the one side that is aligned roughly south, and then on the opposing side, which is aligned roughly north, thin film photovoltaic modules can be used. And a reversed arrangement is also possible. In additional embodiments, crystalline photovoltaic modules are used on both sides.

Since two square photovoltaic modules are arranged oppositely in the photovoltaic system, the photovoltaic system as a whole has to be populated with fewer weighting elements 150 than for conventional photovoltaic systems. Conventional photovoltaic systems, in which one single photovoltaic module is mounted to a supporting triangle, have to be weighted down since wind can penetrate behind the photovoltaic modules and thus cause buoyancy forces on the photovoltaic system. In order to counteract these forces, conventional photovoltaic systems are weighted with about 180-200 kilograms per square meter of mounted photovoltaic module surface area. The substrate thus has to be designed accordingly to support a load of this magnitude. This is not always possible, especially for flat roofs.

In the case of a photovoltaic system, for example, like that described in connection with FIG. 3, photovoltaic module surfaces mounted with weighting elements 150 of about 30 kilograms per square meter are sufficient to hold the photovoltaic system securely to the substrate. Since less wind can penetrate under the photovoltaic module than in conventional photovoltaic systems, the weighting can be reduced, and preferably any additional weighting can be omitted entirely. In addition, with respect to the two oppositely aligned photovoltaic modules, if they are exposed to wind, opposing forces are applied which at least partly cancel each other out. For example, under one of the photovoltaic modules a vacuum pressure forms which pushes the photovoltaic system in the direction of surface 101. Thus it may be sufficient to weight the photovoltaic system at the edge, that is, at base element 108, and on the base element located at the opposite end, whereas on base elements 107 and 160, which are arranged in between, little or no weighting is needed. In addition, it may not be necessary to secure the photovoltaic system by screwing it to the substrate, and/or the number of screw connections can be reduced. Therefore in the case of flat roofs, few or no screw holes through the roofing foil have to be resealed.

The angles 103 and 104 are each large enough so that even at the lowest solar attitude at the side of the photovoltaic system the downside photovoltaic modules located in the direction of solar radiation will not be shadowed by preceding photovoltaic modules. For example, if the solar radiation is directed roughly in the Y-direction, then the photovoltaic modules 157 and 156 are set up obliquely to surface 101 so that the shadows of photovoltaic modules 157 and 156 do not extend to photovoltaic module 149 even at the lowest solar attitude. If the lowest solar attitude is about 18 degrees, for instance, then the photovoltaic modules can be set up at an angle of less than 18 degrees to surface 101, for example, at about 15 degrees. In one sample embodiment, the angle is greater by about 6 degrees so that the photovoltaic modules are subject to self-cleaning, for example, when it rains. Due to this kind of mounting of the photovoltaic modules, the photovoltaic system overall can be populated with a greater surface area of photovoltaic modules for a given base surface area, than a conventional photovoltaic system.

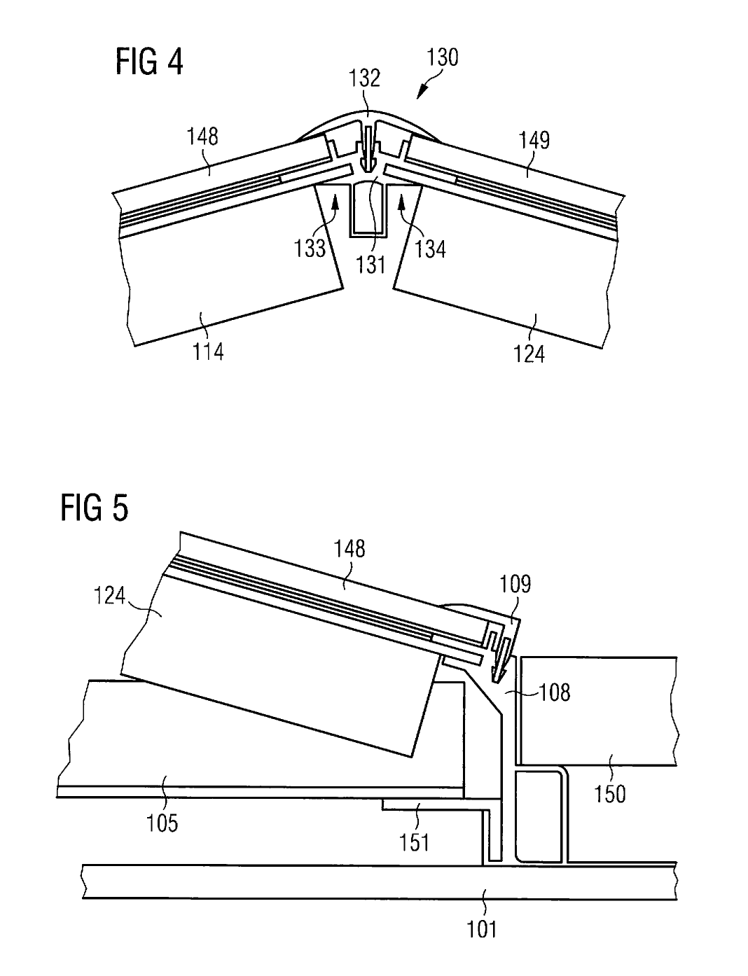

FIG. 4 shows a detailed view of the photovoltaic system with coupling of the elongated rods 114 and 124 and of the photovoltaic modules 148 and 149. The elongated rod 114 engages at a first side 133 into the coupling apparatus 130 and/or into a first element 131 of the coupling apparatus 130. The elongated rod 124 engages at a second side 134 located opposite the first side 133, into the coupling apparatus 130 and/or into a first element 131 of the coupling apparatus 130. In particular, the elongated rods 114 and 124 are each inserted into recesses in the first element. And thus the elongated rods 114 and 124 are coupled together in a self-supporting manner.

If the elongated rods 114 and 124 are coupled to the first element 131 during assembly of the photovoltaic system, then the photovoltaic modules 148 and 149 are placed upon the elongated rods 114 and/or 124. To fix the photovoltaic modules 148 and 149 in position, a second element 132 of the coupling apparatus 130 is coupled to the first element 131. The second element 132 can be friction locked and/or force-locked, for example, to the first element 131 in order to secure the photovoltaic modules 148 and 149 at the first ends 111 and 121. The second element 132 can have elastic elements, for instance, which can then hook into the first element 131. The second element 132 can also be differently coupled to the first element 131, for example, by means of a screw connection.

FIG. 5 shows a detailed view of the photovoltaic system with coupling of the elongated rods 124, of the photovoltaic module 148 and of the elongated rod 105 to the base element 108.

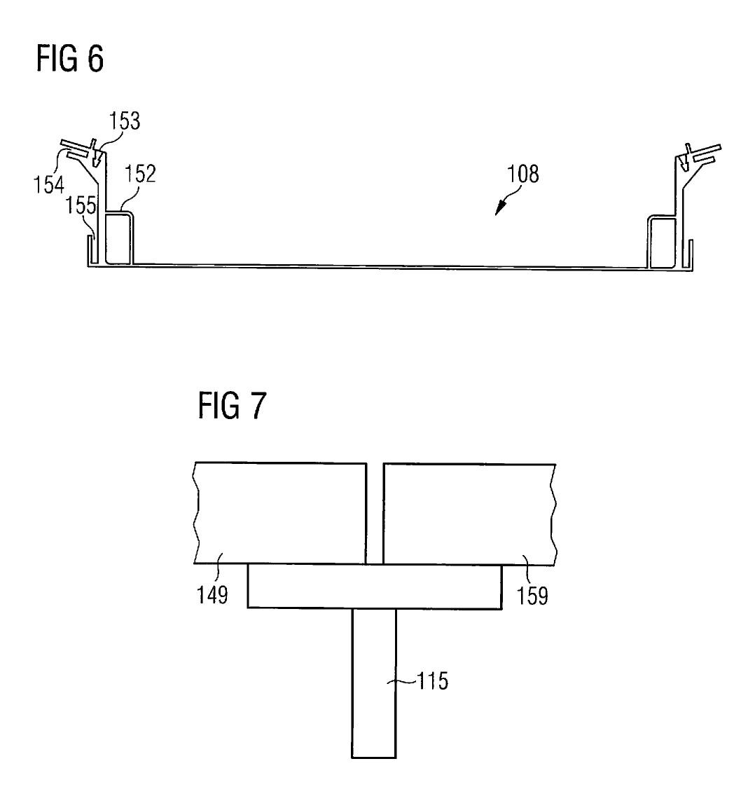

The elongated rod 124 engages into a recess 154 (FIG. 6) of the base element. In particular the elongated rod 124 is inserted into the recess 154 of the base element 108. The photovoltaic module 148, which is resting upon the elongated rod 124, is secured by its second end 122 to an attachment element 109. The attachment element 109 is coupled to the base element 108 at the mount 153 (FIG. 6). The attachment element 109 can be friction-locked and/or force-locked, for example, to the base element 108 in order to secure the photovoltaic module 148. The attachment element 109 can have elastic elements, for instance, which can then hook into the base element 108. The attachment element 109 can also be differently coupled to the base element 108, for example, by means of a screw connection.

The elongated rod 105 is coupled to an angled element 151 for connection to the base element 108. The angled element 151 is coupled to the base element 108, for example, the angled element 151 engages in behind a protruding region 155 (FIG. 6) of the base element 108. In particular, the angled element 151 is inserted into the base element 108. The base element 108 rests upon the surface 101.

The base element 108 lies on the surface 101. The base element 108 touches the surface 101. The weighting element 150 is located on an elevation 152 (FIG. 6) of the base element 108, for example, on a concrete plate. Other weighting elements can also be used, for example, gravel, sand and/or other materials that are suitable for weighting of the base element 108.

FIG. 6 shows a cross section through the base element 108. The base element 108 is of symmetrical design and can then be connected equally on either side to one of the several elongated rods. The base element 108 has a recess 154 for coupling to the elongated rods of the apparatus. The recess 154 is configured so that one or several elongated rods can be inserted therein.

The base element 102 can be coupled to the protruding region 155 of the base element 108. In addition, base element 108 has a mount 153 to which the attachment element for the photovoltaic modules can be coupled. A weighting element, or several weighting elements, can be arranged on the elevation 152. The base element 108 is designed to accommodate electric lines, for example, which are needed for the operation of the photovoltaic system. In addition, base element 108 can be used as a catwalk during assembly or for maintenance of the photovoltaic system.

FIG. 7 shows a cross section of the elongated rod 115 upon which the photovoltaic module 149 and the photovoltaic module 159 are resting. The elongated rod 115 whose cross section has the shape of a T-profile, is designed to accommodate the photovoltaic module 149 and the photovoltaic module 159. The elongated rod is wide enough so that the two photovoltaic modules 149 and 159 rest in regions upon the elongated rod 115 and are mechanically supported reinforced by it; for example, in order to prevent flexure of the photovoltaic modules 149 and 159.

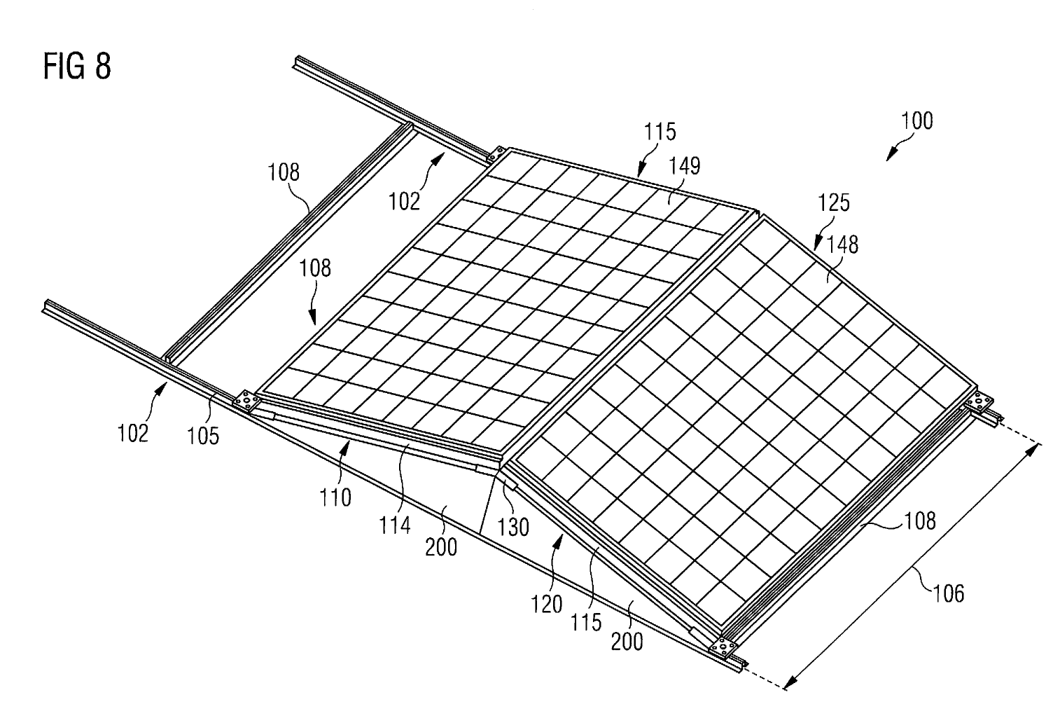

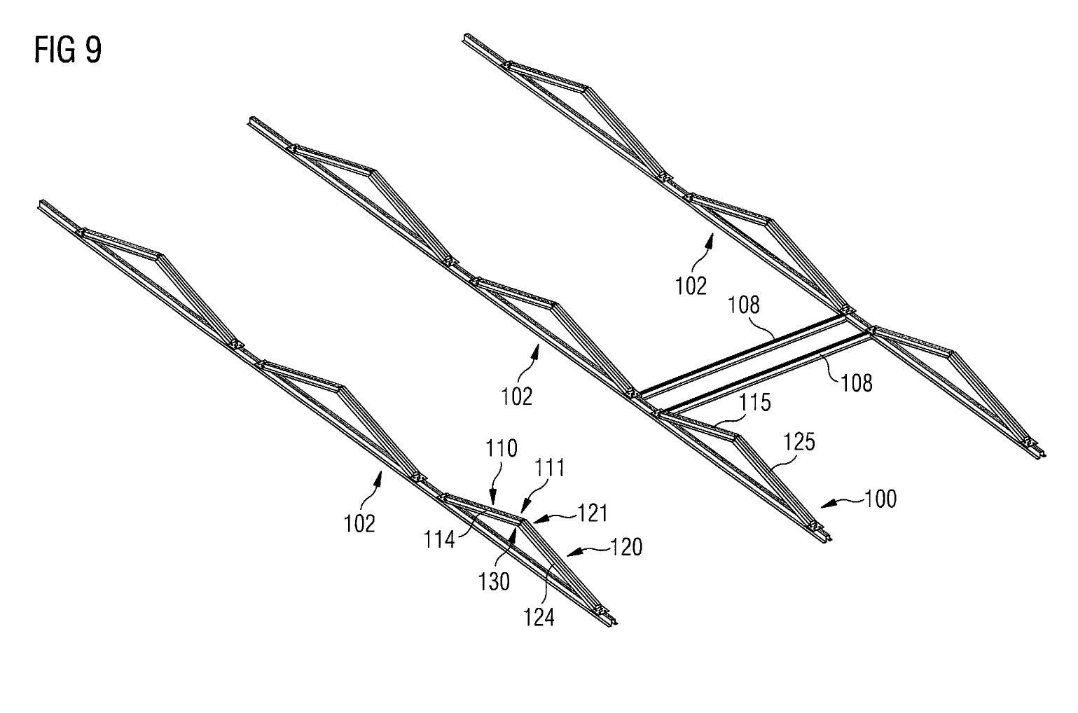

FIG. 8 shows the assembly 100 according to additional exemplary embodiments. In contrast to the exemplary embodiments described in conjunction with FIGS. 1-7, the elongated rods 105, 114, 115, 124, 125 and also the base elements 108 of assembly 100 are of the same type, as will be explained in detail in conjunction with FIG. 9.

The base element 102 according to the exemplary embodiment of FIG. 8 extends across more than one assembly, in particular across a plurality of assemblies along one primary direction of the entire sub-structure, as illustrated in FIG. 9.

To erect the two photovoltaic modules 148 and 149, two base elements 102 are aligned, preferably in parallel, on the surface 101, in particular on the flat roof. The distance 106 of the base elements 102 to each other corresponds essentially to the width of the photovoltaic modules 148, 149. The distance 106 in the exemplary embodiment is established by the base elements 108. The base elements 108 in the exemplary embodiments additionally denote the assembly point for apparatus 110 and 120 and in the finish assembled photovoltaic system they serve to accommodate electric lines which are needed for operation of the photovoltaic system. In addition, base elements 108 can be used as a catwalk during assembly or for maintenance of the photovoltaic system.

In particular in the exemplary embodiments sealing elements 200 can be installed between the base element 102 and the elongated rods 114, 124 at the outsides of the photovoltaic system in order to reduce buoyancy forces acting on the photovoltaic system during wind. The photovoltaic modules are coupled, for example, by means to clamps to elongated rods 114, 124 and/or 115, 125. For instance, the clamps are screwed to the elongated rods 114, 124 and press one frame of the photovoltaic modules against the elongated rods. In the case of photovoltaic modules without frames, so-called edge clamps are used for the coupling.

If a plurality of such assemblies with photovoltaic modules is coupled to one sub-structure and to one photovoltaic system in the finished, operational state, then it is sufficient to place this photovoltaic system upon a flat roof without additional fastening. This is sufficient for a dependable operation since the base elements 102 run across the entire length of the majority of the assemblies and mutually reduce, or preferably eliminate, the buoyancy forces of the photovoltaic modules 148, 149 inclined toward each other. In particular, any additional weighting of the photovoltaic system is omitted entirely.

FIG. 9 shows one exemplary sub-structure with assemblies 100 and/or apparatus 110, 120 according to the embodiment of FIG. 8. The sub-structure can be coupled to two times six photovoltaic modules. To do so, three base elements 102 are provided upon which three sub-apparatus are arranged, each comprising one elongated rod 114 and one elongated rod 124. The sub-apparatus are each coupled to the base element, for example, by soldering or screwing. The elongated rods are coupled to each other at the peak of the sub-apparatus, that is, at the ends 111, 121, for example, they are riveted or screwed to the coupling apparatus 130. At the ends 111, 121 the sub-apparatus are coupled transverse to the longitudinal direction of the base elements 102 and the elongated rods 114, 124 are not connected together. During operation, the apparatus 100 is braced transverse to the longitudinal direction of the base elements 102 by means of the coupled photovoltaic modules. During operation, four photovoltaic modules rest upon the sub-apparatus which are coupled in FIG. 9 onto the middle of the three base elements 102 (elongated rods 115, 125), comparable to the embodiment of the sub-structure as described in conjunction with FIG. 2. The elongated rods 115 and/or 125, respectively, are each designed to support two photovoltaic modules.

The base elements 102, the elongated rods 114 and 124 and also the base elements 108 all have the same cross-sectional shape, in particular a T-shape, and have the same profile.

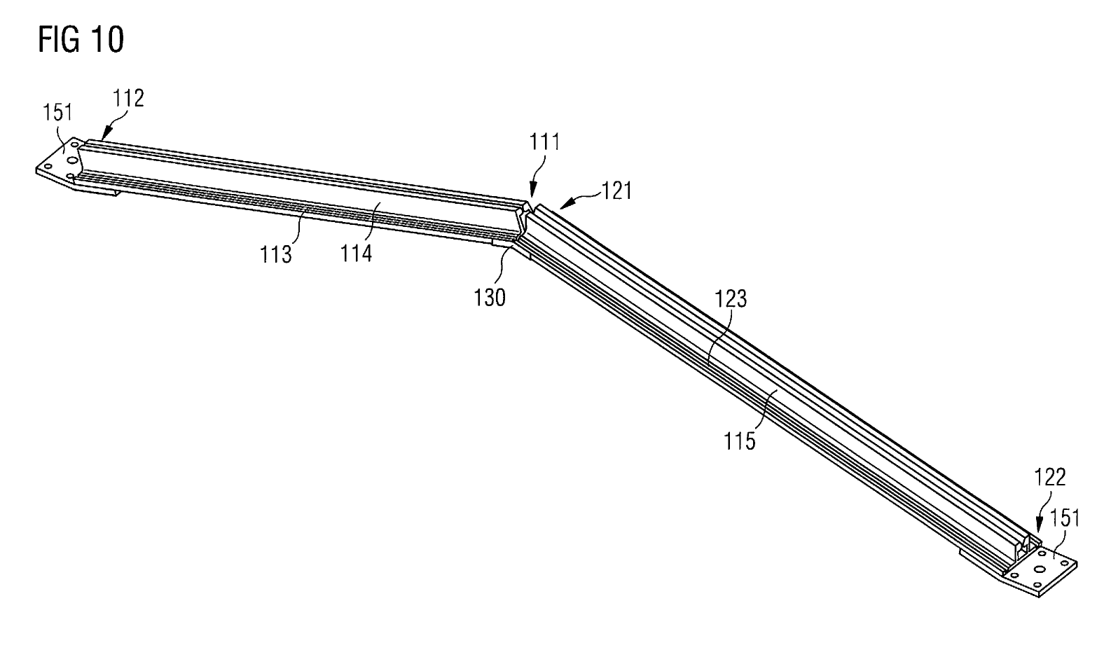

FIG. 10 illustrates the T-shape in detail. FIG. 10 shows a sub-apparatus as described with reference to FIG. 9. The two photovoltaic modules 148 and 149 are each placed upon the two same-directed legs of the T-profile during assembly, so that the third leg, which is directed transverse thereto, is arranged between the two photovoltaic modules 148, 149. The third leg is arranged facing away from the surface 101. The same-directed legs form the accommodation areas 113 and 123. The elongated rods 114 and/or 115 each have two accommodation areas 113 and/or 123 which are arranged on the two opposing sides of the third leg.

One angled element 151 is coupled to the elongated rods 114 and/or 124 at the ends 112 and/or 122. The angled element 151 is coupled to base element 102 during operation, as shown in FIG. 9. The elongated rods 114, 124 are each coupled at their ends 111 and/or 121 to the coupling element 130 that joins the elongated rods 114, 124 together.

In exemplary embodiments the assembly comprises a first base element 107 and a second base element 108, which are each arranged transversely to the longitudinal direction of the elongated rods 114, 115; 124, 125 at a distance to each other on the surface 101, wherein the two elongated rods 114, 115 of the first apparatus 110 are coupled to the first base element 107 at the second end 112 of the first apparatus 110, and the two elongated rods 124, 125 of the second apparatus 120 are coupled to the second base element 108 at the second end 122 of the second apparatus 120.

In the design embodiments, the elongated rods 114, 115; 124, 125 can each be inserted into the base element 107; 108 for coupling in the assembly.

In design embodiments, the base elements 107; 108 can each be designed to accommodate one attachment element 109 for mounting of the particular, at least one photovoltaic module 148; 149, for the assembly.

In the exemplary embodiments, the at least one elongated rod 105 of the base element 102 can be coupled to the first base element 107 and to the second base element 108 in order to couple the first base element 107 to the second base element 108 in the assembly.

The present invention is related to German patent application number 10 2009 041 308.1, which is incorporated herein by reference.

The invention is merely illustrated in an exemplary manner based on the design embodiments in the description and in the figures and is not limited thereto, but rather comprises all variations, modifications, substitutions and combinations which an ordinary person skilled in the art can derive from the presented documents within the scope of the claims and of the general disclosures in the introduction to this description and from the description of the exemplary embodiments. For example, the described assembly and/or the sub-structure can also accommodate thermal solar collectors that convert radiant energy primarily into heat. In particular, all individual features and potential configurations of the invention and of its exemplary embodiments can be combined with one another.

What is claimed is:

1. An assembly, comprising:
a first apparatus having a first end and a second end opposite the first end, the first apparatus to accommodate a photovoltaic module; and
a second apparatus having a first end and a second end opposite the first end, the second apparatus to accommodate a photovoltaic module, wherein the first end of the first apparatus is coupled to the first end of the second apparatus so that the second end of the first apparatus and the second end of the second apparatus are arranged at a distance to each other on a surface that is spaced from a location where the first end of the first apparatus is coupled to the first end of the second apparatus.

2. The assembly according to claim 1, wherein the first apparatus includes an accommodation area that extends from the first end to the second end of the first apparatus and wherein the second apparatus includes an accommodation area that extends from the first end to the second end of the second apparatus.

3. The assembly according to claim 2, further comprising a first photovoltaic module located in the accommodation area of the first apparatus and a second photovoltaic module located in the accommodation area of the second apparatus.

4. The assembly according to claim 1, further comprising a base element connected to the second end of the first apparatus and to the second end of the second apparatus, the base element being arranged on the surface.

5. The assembly according to claim 4, wherein the first apparatus and the second apparatus each form an oblique flank between the first and the second end with respect to the base element, so that the first ends of the first apparatus and of the second apparatus are arranged between the second end of the first apparatus and the second end of the second apparatus.

6. The assembly according to claim 4, wherein the first apparatus and the second apparatus each enclose an angle of less than 90 degrees between the second end and the base element.

7. The assembly according to claim 6, wherein the first apparatus and the second apparatus each enclose an angle of less than 20 degrees between the second end and the base element.

8. The assembly according to claim 6, wherein the angle of the first apparatus and the angle of the second apparatus are of equal size.

9. The assembly according to claim 6, wherein the angle of the first apparatus is different that the angle of the second apparatus.

10. The assembly according to claim 4, wherein the base element comprises an elongated rod that extends from the second end of the first apparatus to the second end of the second apparatus.

11. The assembly according to claim 1, wherein the first apparatus and the second apparatus each comprise at least two elongated rods arranged in the same direction at a distance from each other, each elongated rod extending from the first end to the second end, wherein each elongated rod is designed to accommodate at least one photovoltaic module.

12. The assembly according to claim 11, further comprising a coupling apparatus that couples the first end of the first apparatus to the first end of the second apparatus, wherein the coupling apparatus has a first element and a second element, wherein the elongated rods of the first apparatus and the elongated rods of the second apparatus each engage in opposing sides of the first element in order to couple the first apparatus to the second apparatus, and the second element is designed so as to be coupled to the first element such that a photovoltaic module can be fixed in position at each first end by the coupling apparatus.

13. The assembly according to claim 12, further comprising a first photovoltaic module in position at the first end of the first apparatus and a second photovoltaic module in position at the first end of the second apparatus.

14. The assembly according to claim 1, further comprising at least two triangular-shaped side elements, each triangular-shaped side element being coupled to another triangular-shaped side element at corners of a triangular shape so that three surfaces are enclosed, wherein two surfaces are designed so as to be couplable to a photovoltaic module and a third surface is designed to be arranged on the surface.

15. A sub-structure for a photovoltaic system, the sub-structure comprising:
a first assembly comprising a first apparatus having a first end and a second end opposite the first end and a second apparatus having a first end and a second end opposite the first end, the first and second apparatuses to each accommodate a photovoltaic module, wherein the first end of the first apparatus is coupled to the first end of the second apparatus so that the second end of the first apparatus and the second end of the second apparatus are arranged at a distance to each other on a surface that is spaced from a location where the first end of the first apparatus is coupled to the first end of the second apparatus; and
a second assembly coupled to the first assembly, the second assembly comprising a first apparatus having a first end and a second end opposite the first end and a second apparatus having a first end and a second end opposite the first end, the first and second apparatuses to each accommodate a photovoltaic module, wherein the first end of the first apparatus is coupled to the first end of the second apparatus so that the second end of the first apparatus and the second end of the second apparatus are arranged at a distance to each other on a surface that is spaced from a location where the first end of the first apparatus is coupled to the first end of the second apparatus.

16. The sub-structure according to claim 15, wherein the first apparatus and the second apparatus are coupled together so that the first apparatus is arranged transverse to a longitudinal direction of photovoltaic modules next to the second apparatus.

17. The sub-structure according to claim 15, wherein the first apparatus and the second apparatus are coupled together so that the first apparatus is arranged in a direction of a longitudinal direction of photovoltaic modules next to the second apparatus.

18. A photovoltaic system comprising:
a first apparatus having a first end and a second end opposite the first end;
a second apparatus having a first end and a second end opposite the first end, wherein the first end of the first apparatus is coupled to the first end of the second apparatus so that the second end of the first apparatus and the second end of the second apparatus are arranged at a distance to each other on a surface that is spaced from a location where the first end of the first apparatus is coupled to the first end of the second apparatus;
a first photovoltaic module coupled to the first apparatus; and
a second photovoltaic module coupled to the second apparatus so that a primary surface of incident radiation of the first photovoltaic module is directed differently to a primary surface of incident radiation of the second photovoltaic module.
